(19) United States
(12) Patent Application Publication
(10) Pub. No.: US 2009/0072267 A1
(43) Pub. Date: Mar. 19, 2009

(54) Group III nitride-based compound semiconductor light-emitting device

(75) Inventors: Koichi Goshonoo, Aichi-ken (JP); Miki Moriyama, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/232,320

(22) Filed: Sep. 15, 2008

(30) Foreign Application Priority Data
Sep. 18, 2007 (JP) 2007-240639

(51) Int. Cl. H01L 33/00

(52) U.S. Cl. 257/103; 257/E33.001

(57) ABSTRACT

Provided is a GaN-based semiconductor light-emitting device which does not require an external constant-current circuit. The light-emitting device of the present invention includes a sapphire substrate; an AlN buffer layer formed on the substrate; and an HEMT structure formed on the buffer layer, the HEMT structure including a GaN layer and an Al_{0.2}Ga_{0.8}N layer. On the Al_{0.2}Ga_{0.8}N layer are sequentially formed an n-GaN layer, an MQW light-emitting layer including an InGaN well layer and an AlGaN barrier layer, and a p-GaN layer. A source electrode and an HEMT/LED connection electrode are formed on an exposed portion of the Al_{0.2}Ga_{0.8}N layer. The HEMT/LED connection electrode serves as both the corresponding drain electrode and an electrode for injecting electrons into the n-GaN layer. An ITO transparent electrode is formed on the top surface of the p-GaN layer, and a gold pad electrode is formed on a portion of the top surface of the transparent electrode.

### BACKGROUND OF THE INVENTION

1. Field of the Invention

The present invention relates to a Group III nitride-based compound semiconductor light-emitting device including a constant-current element integrated therewith. As used herein, “Group III nitride-based compound semiconductor” encompasses a semiconductor represented by the formula AlₓGa_{y}In_{1-x-y}N (0≦x≦1, 0≦y≦1, 0≦x+y≦1); such a semiconductor containing a predetermined element so as to attain, for example, an n-type/p-type conduction; and such a semiconductor in which a portion of a Group III element is substituted by B or T1, and a portion of the Group V element is substituted by P, As, Sb, or Bi.

2. Background Art

As has been well known, light output of a light-emitting diode is roughly proportional to the electric current which flows therethrough, and the electric current of the light-emitting diode exponentially increases in accordance with an increase in voltage applied thereto. Therefore, the light-emitting diode requires a drive circuit for supplying constant current, so that the diode emits light having a predetermined range of luminance. Among such circuits, for example, a constant-current diode has been employed.

Japanese Patent Application Laid-Open (kokai) No. 2001-189488 discloses a technique for integrating an optical transmission path with an optical device, as well as combination of the thus-integrated device and another device. Meanwhile, Hsi-Hsuan Yen et al., “GaN Alternating Current Light-Emitting Device,” Phys. Stat. Sol. (a) 204, No. 6, 2077-2081 (2007) describes a circuit in which a plurality of light-emitting diodes are connected between two terminals so that even when either of the two terminals has a higher electric potential, more than half of the light-emitting diodes emit light.

### SUMMARY OF THE INVENTION

In order to provide a Group III nitride-based compound semiconductor light-emitting device which does not require an external constant-current circuit, the present inventors have found that a high electron mobility transistor (HEMT) using, for example; two-dimensional electron gas at a GaN/AlGaN interface, can be employed as a constant-current element. The present invention has been accomplished on the basis of this finding.

In a first aspect of the present invention, there is provided a Group III nitride-based compound semiconductor light-emitting device comprising a light-emitting section having a Group III nitride-based compound semiconductor layered structure, wherein the light-emitting section and a constant-current element formed of a Group III nitride-based compound semiconductor are provided on a common substrate.

In a second aspect of the present invention, the constant-current element is a high electron mobility transistor.

In a third aspect of the present invention, the constant-current element has a Group III nitride-based compound semiconductor layer, and the Group III nitride-based compound semiconductor layer is more proximal to the substrate than is the Group III nitride-based compound semiconductor layered structure forming the light-emitting section.

In a fourth aspect of the present invention, the Group III nitride-based compound semiconductor light-emitting device has at least five light-emitting sections which are diodes, and first to fourth nodes (A, B, C, and D); and

one light-emitting section is connected, or a plurality of light-emitting sections are connected in series between the first node and the second node, between the second node and the fourth node, between the fourth node and the third node, between the third node and the second node, and between the fourth node and the first node, such that when the electric potential at the first node is higher than that at the third node, current flows in a forward direction through all the light-emitting sections connected between the first node and the second node, between the second node and the fourth node, and between the fourth node and the third node, and when the electric potential at the third node is higher than that at the first node, current flows in a forward direction through all the light-emitting sections connected between the third node and the second node, between the second node and the fourth node, and between the fourth node and the first node.

As shown hereinbelow, the layered structure of a Group III nitride-based compound semiconductor light-emitting section can be integrated with the layered structure of a constant-current element. According to the present invention, there can be provided a Group III nitride-based compound semiconductor light-emitting device which does not require an external constant-current circuit. When the Group III nitride-based compound semiconductor light-emitting device of the present invention is employed in a light-emitting apparatus, the size of the entire apparatus can be reduced, which contributes to cost reduction.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a cross-sectional view of the configuration of a Group III nitride-based compound semiconductor light-emitting device 100 according to a specific embodiment of the present invention;

FIG. 2A is a graph showing voltage-current characteristics of the LED section of the Group III nitride-based compound semiconductor light-emitting device 100;

FIG. 2B is a graph showing voltage-current characteristics of the HEMT section of the Group III nitride-based compound semiconductor light-emitting device 100;

FIG. 2C is a graph showing voltage-current characteristics of the entirety of the Group III nitride-based compound semiconductor light-emitting device 100;

FIG. 3 is a cross-sectional view of the configuration of a Group III nitride-based compound semiconductor light-emitting device 150 according to a modification;

FIG. 4 is a cross-sectional view of the configuration of a Group III nitride-based compound semiconductor light-emitting device 200 according to another specific embodiment of the present invention;

FIG. 5 is a cross-sectional view of the configuration of a Group III nitride-based compound semiconductor light-emitting device 300 according to yet another specific embodiment of the present invention;

FIG. 6A is a circuit diagram of a Group III nitride-based compound semiconductor light-emitting device according to Embodiment 4;

FIG. 6B is a circuit diagram of a Group III nitride-based compound semiconductor light-emitting device according to Comparative Embodiment;

FIG. 7A is a graph showing change over time in current of the light-emitting device according to Embodiment 4;

FIG. 7B is a graph showing change over time in current of the light-emitting device according to the Comparative Embodiment; and

FIG. 7C is a graph showing change over time in voltage of applied electric power (100 V, 50 Hz).

### DETAILED DESCRIPTION OF PREFERRED EMBODIMENTS

The present invention preferably employs, as a constant-current element, an HEMT formed of a Group III nitride-based compound semiconductor. In such an HEMT, high-mobility two-dimensional electron gas can be generated at high concentration, by virtue of, for example, spontaneous polarization attributed to an AlGaN/GaN heterojunction, and piezoelectric polarization induced by interfacial stress. Such an HEMT is of a so-called normally-on type.

The constant-current element employed in the present invention may have any other known HEMT structure. The constant-current element may have another element structure; i.e., saturation current characteristics of another element.

In the present invention, no particular limitation is imposed on the configuration of a light-emitting section into which the constant-current element is incorporated.

The light-emitting section and the constant-current element may be provided on the same side of a substrate, or may be respectively provided on both sides of the substrate. Alternatively, the light-emitting device may be produced through the following procedure: the layered structures of the light-emitting section and the constant-current element are formed on an epitaxial growth substrate; the epitaxial growth substrate is removed; and the light-emitting section and the constant-current element are bonded to another substrate.

### EMBODIMENT 1

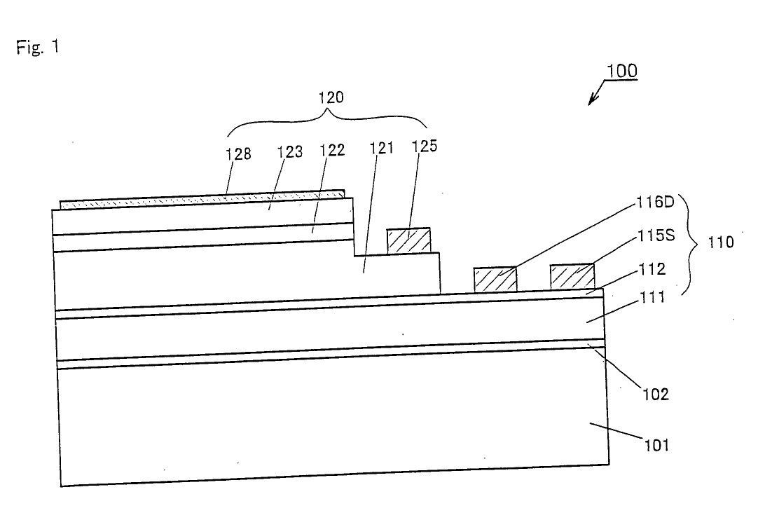

FIG. 1 is a cross-sectional view of the configuration of a Group III nitride-based compound semiconductor light-emitting device 100 according to Embodiment 1 of the present invention. In the light-emitting device 100, the below-described layers are epitaxially grown through the widely known MOCVD technique.

An AlN buffer layer 102 (thickness: 200 nm) is formed on a sapphire substrate 101.

An HEMT section (constant-current element) 110 is configured as described below.

An undoped GaN layer 111 (thickness: 1 μm) is formed on the AlN buffer layer 102, and an undoped or silicon-doped Al_{0.2}Ga_{0.8}N layer 112 (thickness: 45 nm) is formed on the GaN layer 111. After formation of the layers of the below-described LED section (light-emitting section) 120, a portion of the Al_{0.2}Ga_{0.8}N layer 112 is exposed through reactive ion etching, and a source electrode 115S and a drain electrode 116D, each having a double-layer structure of vanadium (V) and aluminum (Al), are formed on the exposed portion of the Al_{0.2}Ga_{0.8}N layer 112. The source electrode 115S and the drain electrode 116D are provided so that the distance between the electrodes (channel length) is 8 μm and the channel width is 600 μm. Two-dimensional electron gas is generated at a portion of the GaN layer 111 at the interface between the GaN layer 111 and the Al_{0.2}Ga_{0.8}N layer 112, whereby a channel is formed.

Alternatively, wet etching may be employed for exposure of a portion of the Al_{0.2}Ga_{0.8}N layer 112.

An LED section (light-emitting section) 120 is configured as described below.

A silicon-doped n-GaN layer 121 (thickness 3.5 μm) is formed on the Al_{0.2}Ga_{0.8}N layer 112. An MQW light-emitting layer 122 including eight InGaN well layers and AlGaN barrier layers is formed on the n-GaN layer 121. A magnesium-doped p-GaN layer 123 (thickness: 100 nm) is formed on the MQW light-emitting layer 122.

A portion of the top surface of the n-GaN layer 121 is exposed through reactive ion etching, and an n-electrode 125 having a double-layer structure of vanadium (V) and aluminum (Al) is formed on the exposed portion of the n-GaN layer 121. An ITO transparent electrode 128 (thickness: 300 nm) is formed on the top surface of the p-GaN layer 123. The MQW light-emitting layer 122 is formed so as to have a horizontal surface area of 240 μm×480 μm.

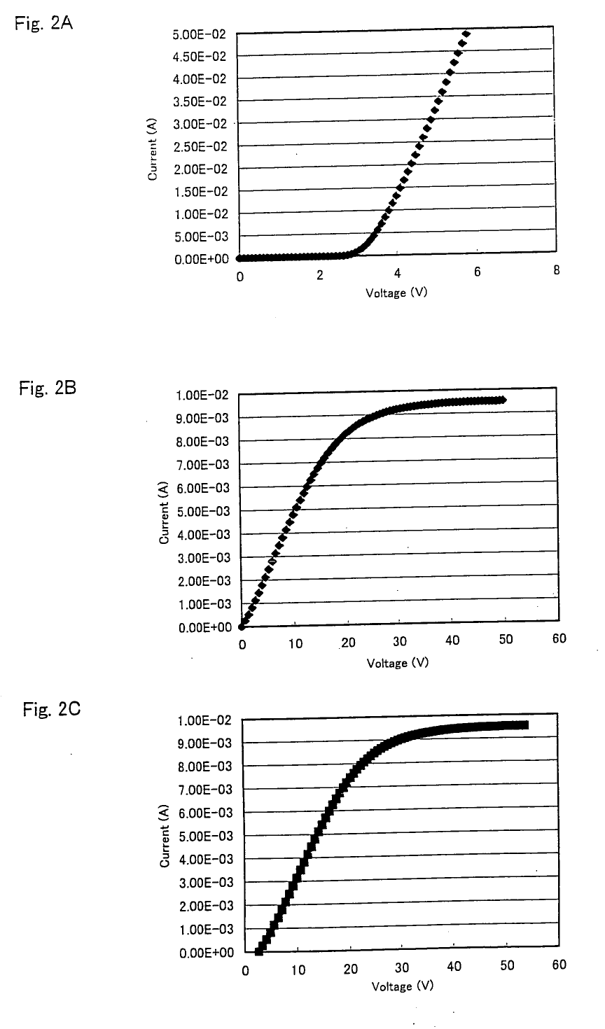

For evaluation of voltage-current characteristics of the LED section 120 of the Group III nitride-based compound semiconductor light-emitting device 100 shown in FIG. 1, a probe was brought into contact with the n-electrode 125 and the transparent electrode 128 of the LED section 120. FIG. 2A is a graph showing voltage-current characteristics of the LED section 120 of the Group III nitride-based compound semiconductor light-emitting device 100. As shown in FIG. 2A, current flowed through the LED section 120 upon application of a voltage of about 2.8 V or more. A current of 10 mA flowed therethrough upon application of a voltage of 3.8 V.

For evaluation of voltage-current characteristics of the HEMT section 110 of the Group III nitride-based compound semiconductor light-emitting device 100 shown in FIG. 1, a probe was brought into contact with the source electrode 115S and the drain electrode 116D of the HEMT section 110. FIG. 2B is a graph showing voltage-current characteristics of the HEMT section 110 of the Group III nitride-based compound semiconductor light-emitting device 100. In the HEMT section 110, current reached 8 mA upon application of a voltage of 20 V, and current was maintained almost constant at 9.2 to 9.5 mA upon application of a voltage of 30 to 50 V (saturation current).

FIG. 2C is a graph showing voltage-current characteristics of the entirety of the Group III nitride-based compound semiconductor light-emitting device 100. For evaluation of voltage-current characteristics of the entire light-emitting device 100, the drain electrode 116D was connected to the n-electrode 125 so that the HEMT section 110 and the LED section 120 were connected in series.

As shown in FIG. 2A, in the LED section 120 of the Group III nitride-based compound semiconductor light-emitting device 100 shown in FIG. 1, a current of 7 mA flows upon application of a voltage of 3.6 V; a current of 10 mA flows upon application of a voltage of 3.8 V; and a current of 13 mA flows upon application of a voltage of 4.0 V. That is, in the LED section 120, current varies within a range of ±30% in accordance with variation in voltage within a range of ±5% with respect to an applied voltage of 3.8 V.

In contrast, as is clear from FIG. 2C, in the entirety of the Group III nitride-based compound semiconductor light-emitting device 100, which includes the HEMT section 110, a current of 9.5 mA flows upon application of a voltage of 50 V, and current varies only within a range of ±0.1% or less in accordance with variation in voltage within a range of ±5%.

Thus, the Group III nitride-based compound semiconductor light-emitting device, which includes the constant-current element integrated therewith, exhibits small variation in current with respect to variation in voltage.

In the HEMT section 110, the GaN layer 111 may have a thickness of 1 to 4 μm, and the Al_{0.2}Ga_{0.8}N layer 112 may have a thickness of 15 to 45 nm. The source electrode 115S, the drain electrode 116D, or the n-electrode 125 may have a double-layer structure formed of titanium (Ti) and aluminum (Al), or a double-layer structure formed of titanium (Ti) and nickel (Ni).

### Modification

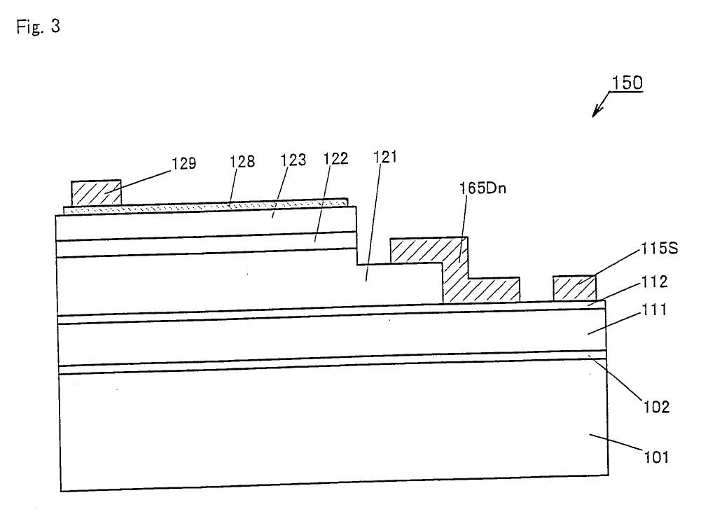

FIG. 3 is a cross-sectional view of the configuration of a Group III nitride-based compound semiconductor light-emitting device 150 according to a modification. The Group III nitride-based compound semiconductor light-emitting device 150 shown in FIG. 3 has the same configuration as the Group III nitride-based compound semiconductor light-emitting device 100 shown in FIG. 1, except that the drain electrode 116D and the n-electrode 125 are substituted by an integrated HEMT/LED connection electrode 165Dn, and that a pad electrode 129 formed of nickel (Ni) and gold (Au) is provided on a portion of the top surface of the ITO transparent electrode.

### EMBODIMENT 2

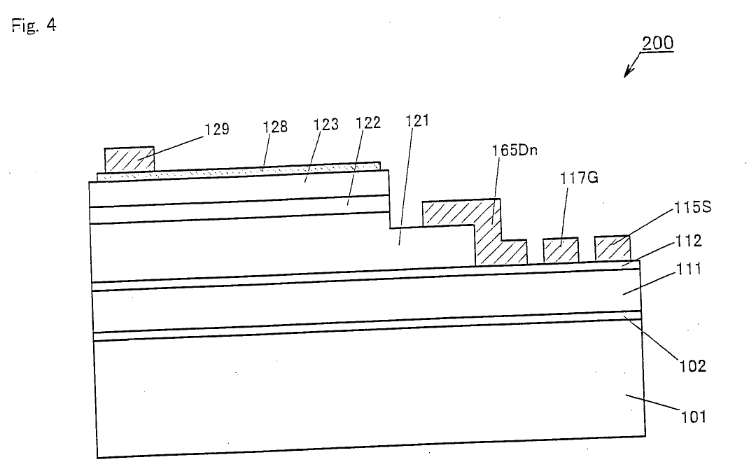

FIG. 4 is a cross-sectional view of the configuration of a Group III nitride-based compound semiconductor light-emitting device 200 according to Embodiment 2 of the present invention. The Group III nitride-based compound semiconductor light-emitting device 200 shown in FIG. 4 has the same configuration as the Group III nitride-based compound semiconductor light-emitting device 150 shown in FIG. 3, except that a gate electrode 117G formed of nickel (Ni) and gold (Au), which is a Schottky electrode, is provided between the source electrode 115S and the HEMT/LED connection electrode 165Dn.

The Group III nitride-based compound semiconductor light-emitting device 100 shown in FIG. 1 or the Group III nitride-based compound semiconductor light-emitting device 150 shown in FIG. 3 is of a normally-on type in which high-mobility two-dimensional electron gas is generated at high concentration by virtue of an AlGaN/GaN heterojunction. In contrast, in the Group III nitride-based compound semiconductor light-emitting device 200 shown in FIG. 4, which includes the gate electrode 117G, saturation current between the source electrode 115S and the HEMT/LED connection electrode 165Dn can be controlled through application of negative electric potential to the gate electrode 117G. That is, current supplied to the LED section 120 can be controlled by electric potential applied to the gate electrode 117G, to thereby vary the intensity of light emitted from the light-emitting layer 122 of the LED section 120.

### EMBODIMENT 3

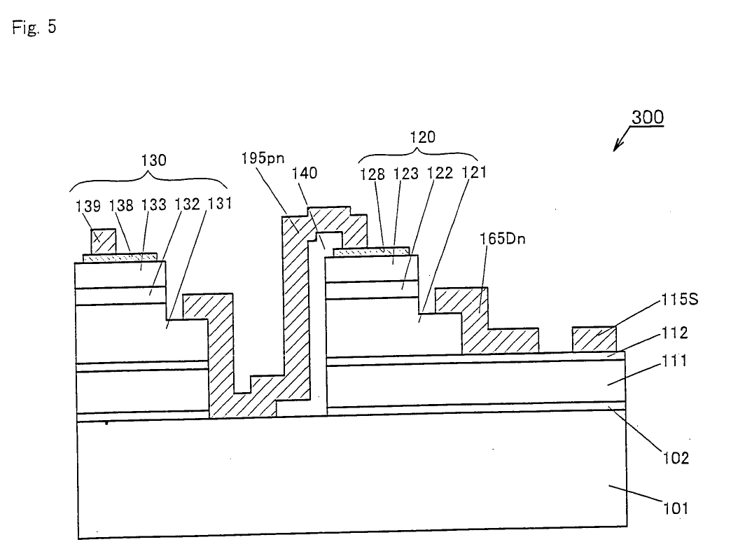

FIG. 5 is a cross-sectional view of the configuration of a Group III nitride-based compound semiconductor light-emitting device 300 according to Embodiment 3 of the present invention. The Group III nitride-based compound semiconductor light-emitting device 300 shown in FIG. 5 includes an LED section 130 having a configuration similar to that of the LED section 120 of the Group III nitride-based compound semiconductor light-emitting device 150 shown in FIG. 3. In the light-emitting device 300, the transparent electrode 128 provided on the p-GaN layer 123 of the LED section 120 is connected to an n-GaN layer 131 of the LED section 130 by an inter-LED connection electrode 195pn. The LED section 130 includes the silicon-doped n-GaN layer 131, an MQW light-emitting layer 132, a p-GaN layer 133, and an ITO transparent electrode 138, which are respectively insulated from the corresponding layers and electrode of the LED section 120. A pad electrode 139 is formed on the transparent electrode 138. For prevention of short circuit, the LED section 120 and the LED section 130 are provided so as to be separated from each other by a gap (i.e., an exposed portion of the sapphire substrate 101), so that the LED section 120 and the LED section 130 are not connected via a semiconductor layer. In addition, an insulating film 140 is formed on the LED section 120 so that the inter-LED connection electrode 195pn does not come into contact with the exposed surfaces of the Group III nitride-based compound semiconductor layers, except for the transparent electrode 128 (i.e., the top surface and side surface of the p-GaN layer 123., and the side surfaces of the MQW light-emitting layer 122, the n-GaN layer 121, the Al_{0.2}Ga_{0.8}N layer 112, the GaN layer 111, and the AlN buffer layer 102).

The Group III nitride-based compound semiconductor light-emitting device 300 shown in FIG. 5 includes the two light-emitting sections; i.e., the LED sections 120 and 130. In the same manner as described above, a predetermined number of LED sections may be connected in series in the light-emitting device; for example, the transparent electrode 138 of the LED section 130 may be connected to an n-GaN layer of the third LED section by an inter-LED connection electrode, and then the transparent electrode of the third LED may be connected to an n-GaN layer of the fourth LED by an inter-LED connection electrode. When a plurality of LED sections are provided, in some cases, all the LED sections are not connected in series as described in the following embodiment.

### EMBODIMENT 4

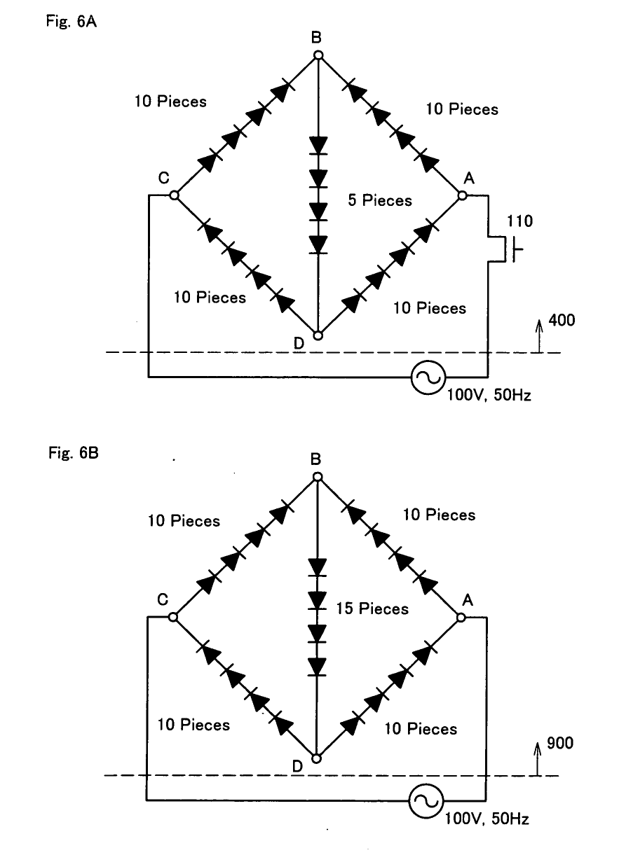

FIG. 6A is a circuit diagram of the configuration of a Group III nitride-based compound semiconductor light-emitting device 400 according to Embodiment 4, the device including a plurality of LED sections. FIG. 6A does not show all the LED sections of the light-emitting device 400. In FIG. 6A, the numeral beside a series connection of four LED sections denotes the actual number of LED sections provided in the series connection (the same shall apply in FIG. 6B described below).

As shown in FIG. 6A, in the Group III nitride-based compound semiconductor light-emitting device 400, 45 LED sections are connected to an HEMT section 110 via first to fourth nodes A, B, C, and D as follows.

Ten LED sections are connected in series between the nodes A and B so that when the electric potential at the node A is higher than that at the node B, current flows in a forward direction.

Five LED sections are connected in series between the nodes B and D so that when the electric potential at the node B is higher than that at the node D, current flows in a forward direction.

Ten LED sections are connected in series between the nodes D and C so that when the electric potential at the node D is higher than that at the node C, current flows in a forward direction.

Ten LED sections are connected in series between the nodes C and B so that when the electric potential at the node C is higher than that at the node B, current flows in a forward direction.

Ten LED sections are connected in series between the nodes D and A so that when the electric potential at the node D is higher than that at the node A, current flows in a forward direction.

The drain electrode of the HEMT section 110 is connected to the node A. The source electrode of the HEMT section 110 is connected to one terminal of an AC power supply, and the other terminal of the AC power supply is connected to the node C.

In the Group III nitride-based compound semiconductor light-emitting device 400 shown in FIG. 6A, when the electric potential at the node A is higher than that at the node C, current flows through the 25 LED sections which are connected in series sequentially from the node A, via the nodes B and D, to the node C, and the 25 LED sections emit light. In this case, current does not flow through the 20 LED sections which are provided between the nodes C and B and between the nodes D and A, and the 20 LED sections do not emit light.

In contrast, when the electric potential at the node C is higher than that at the node A, current flows through the 25 LED sections which are connected in series sequentially from the node C, via the nodes B and D, to the node A, and the 25 LED sections emit light. In this case, current does not flow through the 20 LED sections which are provided between the nodes A and B and between the nodes D and C, and the 20 LED sections do not emit light.

Thus, in the Group III nitride-based compound semiconductor light-emitting device 400 shown in FIG. 6A, the 45 LED sections are connected in series/parallel, and, when the electric potential is high at either the node A or the node C, 25 LED sections of the 45 LED sections (i.e., more than half of all the LED sections) emit light. The light-emitting device 400 includes the HEMT section 110 integrated therewith.

### COMPARATIVE EMBODIMENT

FIG. 6B is a circuit diagram of the configuration of a Group III nitride-based compound semiconductor light-emitting device 900 according to the Comparative Embodiment, the device including a plurality of LED sections.

The Group III nitride-based compound semiconductor light-emitting device 900 shown in FIG. 6B has the same configuration as the Group III nitride-based compound semiconductor light-emitting device 400 shown in FIG. 6A, except that the HEMT section 110 is removed; an AC power supply is connected directly to the nodes A and C; and 15 LED sections are connected in series between the nodes B and D so that when the electric potential at the node B is higher than that at the node D, current flows in a forward direction.

In the Group III nitride-based compound semiconductor light-emitting device 900 shown in FIG. 6B, when the electric potential at the node A is higher than that at the node C, current flows through the 35 LED sections which are connected in series sequentially from the node A, via the nodes B and D, to the node C, and the 35 LED sections emit light. In this case, current does not flow through the 20 LED sections which are provided between the nodes C and B and between the nodes D and A, and the 20 LED sections do not emit light.

In contrast, when the electric potential at the node C is higher than that at the node A, current flows through the 35 LED sections which are connected in series sequentially from the node C, via the nodes B and D, to the node A, and the 35 LED sections emit light. In this case, current does not flow through the 20 LED sections which are provided between the nodes A and B and between the nodes D and C, and the 20 LED sections do not emit light.

Thus, in the Group III nitride-based compound semiconductor light-emitting device 900 shown in FIG. 6B, the 55 LED sections are connected in series/parallel, and, when the electric potential is high at either the node A or the node C, 35 LED sections of the 55 LED sections (i.e., more than half of all the LED sections) emit light.

Commercial electric power (100 V, 50 Hz) was applied to the Group III nitride-based compound semiconductor light-emitting device 400 shown in FIG. 6A and to the Group III nitride-based compound semiconductor light-emitting device 900 shown in FIG. 6B for evaluation of current characteristics.

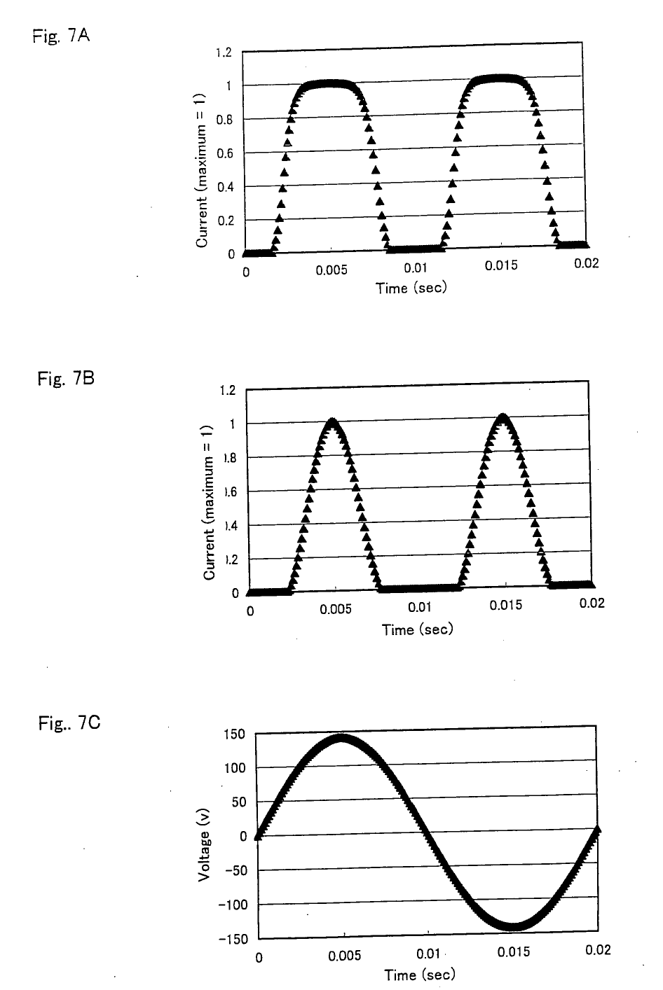

FIG. 7A is a graph showing change over time in current of the Group III nitride-based compound semiconductor light-emitting device 400 shown in FIG. 6A; FIG. 7B is a graph showing change over time in current of the Group III nitride-based compound semiconductor light-emitting device 900 shown in FIG. 6B; and FIG. 7C is a graph showing change over time in voltage of applied electric power (100 V, 50 Hz). An AC power supply (effective voltage: 100 V, frequency: 50 Hz) was employed (i.e., voltage amplitude=141 V, cycle=0.02 seconds) (FIG. 7C). As is clear from FIGS. 7A and 7B, in both the Group III nitride-based compound semiconductor light-emitting devices 400 and 900, at an interval of 0.01 seconds, current flows alternately through the LED sections connected in series between the nodes A, B, D, and C, or through the LED sections connected in series between the nodes C, B, D, and A, whereby light is emitted therefrom.

The ratio of the time during which a current equal to or greater than the half of the maximum current flows to the time of one cycle is about 0.5 (see FIG. 7A) in the case of the Group III nitride-based compound semiconductor light-emitting device 400 shown in FIG. 6A, which includes the HEMT section 110, whereas the time ratio is as low as about 0.3 (see FIG. 7B) in the case of the Group III nitride-based compound semiconductor light-emitting device 900 shown in FIG. 6B, which includes no HEMT section. As is clear from these data, the Group III nitride-based compound semiconductor light-emitting device 400 shown in FIG. 6A, which includes the HEMT section 110, emits light of high luminance for a long period of time and exhibits reduced flickering, as compared with the Group III nitride-based compound semiconductor light-emitting device 900 shown in FIG. 6B, which includes no HEMT section.

When the maximum current of the Group III nitride-based compound semiconductor light-emitting device 400 is controlled to be equal to that of the Group III nitride-based compound semiconductor light-emitting device 900, the effective current in each half cycle of AC current is greater in the light-emitting device 400 (see FIG. 7A) than in the light-emitting device 900 (see FIG. 7B). In other words, the light-emitting device 400 shown in FIG. 6A, which includes the HEMT section 110, exhibits large effective current and emits light of high luminance, as compared with the light-emitting device 900 shown in FIG. 6B, which includes no HEMT section.

Thus, the Group III nitride-based compound semiconductor light-emitting device provided by the present invention, which includes the HEMT section integrated therewith, emits light of high luminance for a longer period of time and exhibits reduced flickering.

### OTHER EMBODIMENTS

In the aforementioned embodiments, description has been focused on integration of the light-emitting section and the constant-current element, which are main components of the light-emitting device of the present invention, and which are formed of a Group III nitride-based compound semiconductor layered structure. Therefore, the light-emitting section has been described by taking, as an example, only a light-emitting section having a very simple structure. However, the light-emitting device may include a light-emitting section having the below-described layered structure. Specifically, on the AlGaN layer 112 (i.e., the uppermost layer of the HEMT section (constant-current element) 110) may be sequentially provided the following layers:

an n-contact layer formed of a silicon-doped n-type GaN layer;

a layer for improving electrostatic breakdown voltage formed by sequentially stacking an undoped GaN layer and an n-type GaN layer;

an n-cladding layer including at least a silicon-doped layer, and including, for example, multiple layers of InGaN and GaN;

a light-emitting layer having a multiple quantum well structure including, for example, an InGaN well layer and double barrier layers of GaN and AlGaN;

a magnesium-doped p-cladding layer formed of, for example, multiple layers of InGaN and AlGaN; and

a p-contact layer formed of double layers having different magnesium concentrations.

The thickness, dopant concentration, number, and growth conditions (e.g., growth temperature) of the layers forming the aforementioned layered structure may be appropriately determined to fall within ranges generally known in the art. Alternatively, instead of providing a simply repeated layered structure, thickness, dopant concentration, or growth conditions (e.g., growth temperature) may be appropriately regulated so as to form, for example, the first or last layer of the layered structure which comes into contact with another functional layer, or a layer in the vicinity of the first or last layer. Another known layer having a function different from that of any of the. aforementioned layers, or another known technique may be applied to the light-emitting section of the light-emitting device of the present invention.

The constant-current element may have, instead of the aforementioned layered structure formed of a GaN layer and an AlGaN layer, a structure formed of another known Group III nitride-based compound semiconductor.

An example of the aforementioned layered structure of the light-emitting section is as follows.

The layer for improving electrostatic breakdown voltage is formed of an undoped GaN layer (thickness: 300 nm) and an n-GaN layer (thickness: 30 nm).

The n-cladding layer (total thickness: about 74 nm) is formed of 10 layer units, each unit including an undoped In_{0.1}Ga_{0.9}N layer, an undoped GaN layer, and a silicon (Si)-doped GaN layer.

The light-emitting layer is formed by alternately stacking eight In_{0.2}Ga_{0.8}N well layers, each having a thickness of about 3 nm, and eight barrier layers, each including a GaN layer (thickness: about 2 nm) and an A1_{0.06}Ga_{0.94}N layer (thickness: 3 nm).

The p-cladding layer (total thickness: about 33 nm) is formed of multiple layers including a p-type Al_{0.3}Ga_{0.7}N layer and a p-type In_{0.08}Ga_{0.92}N layer.

The p-contact layer (total thickness: about 80 nm) has a layered structure including two p-type GaN layers having different magnesium concentrations.

What is claimed is:

1. A Group III nitride-based compound semiconductor light-emitting device comprising a light-emitting section having a Group III nitride-based compound semiconductor layered structure, wherein the light-emitting section and a constant-current element formed of a Group III nitride-based compound semiconductor are provided on a common substrate.

2. A Group III nitride-based compound semiconductor light-emitting device as described in claim 1, wherein the constant-current element is a high electron mobility transistor.

3. A Group III nitride-based compound semiconductor light-emitting device as described in claim 1, wherein the constant-current element has a Group III nitride-based compound semiconductor layer, and the Group III nitride-based compound semiconductor layer is more proximal to the substrate than is the Group III nitride-based compound semiconductor layered structure forming the light-emitting section.

4. A Group III nitride-based compound semiconductor light-emitting device as described in claim 2, wherein the constant-current element has a Group III nitride-based compound semiconductor layer, and the Group III nitride-based compound semiconductor layer is more proximal to the substrate than is the Group III nitride-based compound semiconductor layered structure forming the light-emitting section.

5. A Group III nitride-based compound semiconductor light-emitting device as described in claim 1, wherein the Group III nitride-based compound semiconductor light-emitting device has at least five light-emitting sections which are diodes, and first to fourth nodes (A, B, C, and D); and
one light-emitting section is connected, or a plurality of light-emitting sections are connected in series between the first node and the second node, between the second node and the fourth node, between the fourth node and the third node, between the third node and the second node, and between the fourth node and the first node, such that when the electric potential at the first node is higher than that at the third node, current flows in a forward direction through all the light-emitting sections connected between the first node and the second node, between the second node and the fourth node, and between the fourth node and the third node, and when the electric potential at the third node is higher than that at the first node, current flows in a forward direction through all the light-emitting sections connected between the third node and the second node, between the second node and the fourth node, and between the fourth node and the first node.

6. A Group III nitride-based compound semiconductor light-emitting device as described in claim 2, wherein the Group III nitride-based compound semiconductor light-emitting device has at least five light-emitting sections which are diodes, and first to fourth nodes (A, B, C, and D); and
one light-emitting section is connected, or a plurality of light-emitting sections are connected in series between the first node and the second node, between the second node and the fourth node, between the fourth node and the third node, between the third node and the second node, and between the fourth node and the first node, such that when the electric potential at the first node is higher than that at the third node, current flows in a forward direction through all the light-emitting sections connected between the first node and the second node, between the second node and the fourth node, and between the fourth node and the third node, and when the electric potential at the third node is higher than that at the first node, current flows in a forward direction through all the light-emitting sections connected between the third node and the second node, between the second node and the fourth node, and between the fourth node and the first node.

7. A Group III nitride-based compound semiconductor light-emitting device as described in claim 3, wherein the Group III nitride-based compound semiconductor light-emitting device has at least five light-emitting sections which are diodes, and first to fourth nodes (A, B, C, and D); and
one light-emitting section is connected, or a plurality of light-emitting sections are connected in series between the first node and the second node, between the second node and the fourth node, between the fourth node and the third node, between the third node and the second node, and between the fourth node and the first node, such that when the electric potential at the first node is higher than that at the third node, current flows in a forward direction through all the light-emitting sections connected between the first node and the second node, between the second node and the fourth node, and between the fourth node and the third node, and when the electric potential at the third node is higher than that at the first node, current flows in a forward direction through all the light-emitting sections connected between the third node and the second node, between the second node and the fourth node, and between the fourth node and the first node.

8. A Group III nitride-based compound semiconductor light-emitting device as described in claim 4, wherein the Group III nitride-based compound semiconductor light-emitting device has at least five light-emitting sections which are diodes, and first to fourth nodes (A, B, C, and D); and
one light-emitting section is connected, or a plurality of light-emitting sections are connected in series between the first node and the second node, between the second node and the fourth node, between the fourth node and the third node, between the third node and the second node, and between the fourth node and the first node, such that when the electric potential at the first node is higher than that at the third node, current flows in a forward direction through all the light-emitting sections connected between the first node and the second node, between the second node and the fourth node, and between the fourth node and the third node, and when the electric potential at the third node is higher than that at the first node, current flows in a forward direction through all the light-emitting sections connected between the third node and the second node, between the second node and the fourth node, and between the fourth node and the first node.
